(19) United States
(12) Patent Application Publication
(10) Pub. No.: US 2009/0266417 A1
(43) Pub. Date: Oct. 29, 2009

(54) DYE SENSITIZED SOLAR CELL

(76) Inventors: Julie Baker, Hertfordshire (GB); Nicholas J. Dartnell, Cambridgeshire (GB)

Correspondence Address: EASTMAN KODAK COMPANY;PATENT LEGAL STAFF, 343 STATE STREET, ROCHESTER, NY, 14650-2201, US

(21) Appl. No.: 12/439,202

(22) PCT Filed: Aug. 31, 2007
(86) PCT No.: PCT/GB07/03285

§ 371 Date: Feb. 27, 2009

(30) Foreign Application Priority Data
Sep. 15, 2006 (GB) 0618169.7

(51) Int. Cl. H01L 31/00

(52) U.S. Cl. 136/256

(57) ABSTRACT

A photovoltaic device comprises an anode having a film of semi conductive particles deposited on a substrate, an electrolyte and a cathode. The anode comprises a single porous layer formed of a combination of two particle sizes of a metal oxide.

### FIELD OF THE INVENTION

The present application relates to the field of photochemical cells, in particular to a method of improving the initial performance and reducing the decay rate of a dye sensitised solar cell.

### BACKGROUND OF THE INVENTION

Dye-sensitised solar cells (DSSCs) were first publicly demonstrated by Professor M. Graetzel in the early 1990s and their potential for enabling cheap photovoltaic devices by virtue of low materials and processing costs was immediately recognised. Following much academic research, the energy conversion efficiency of cells made on glass substrates with liquid electrolytes has steadily increased to around 10% (AM1.5, 1 Sun conditions). As a consequence there has been mounting commercial interest in this type of technology. Although work on glass-based DSSCs continues the last few years have seen a marked trend toward developing Graetzel cells with solid electrolytes on plastic substrates (PDSCs). The flexible format is seen as offering advantages over glass in volume manufacture and in end-use versatility. Flexible amorphous silicon (a-Si) modules are now commercially available for the leisure market.

Flexible, organic solar cells such as those based on carbon nano-tubes and hole-conducting polymer electrolytes are also emerging as contenders for low-power PV applications, and there are now regular claims in the literature regarding record efficiencies for Graetzel and organic solar cells (the latest figures are around 10% for glass DSCs, 5% for PDSCs and 5% for organic cells).

Good progress has been made in the development of a plastic substrate, gelled electrolyte Graetzel cell with performances of 5% efficiency being achieved under indoor light—a higher performance than a commercial, flexible a-Si cell yielded. However, PDSC efficiencies drop below a-Si as the light intensity is further increased up to 1-Sun.

In a dye sensitised solar cell, a working electrode is constructed by forming a dye sensitised porous film with oxide semiconductor fine particles (such as nanoparticles of titanium dioxide or the like) on a transparent conductive substrate. This working electrode is used with a counter electrode and the space between the two electrodes is filled with an electrolyte solution that contains a redox pair (such as I⁻/I₃⁻).

Such a dye-sensitized solar cell functions as a photovoltaic device that converts light energy into electricity when oxide semiconductor fine particles are sensitized by a dye that absorbs incident light, thereby generating an electromotive force between the working electrode and counter electrode.

Materials that promote the oxidation-reduction reaction of the redox couple on the surface of the electrode are desirable for use as the counter electrode, and platinum is preferred.

For the commercialisation of such a dye sensitised solar cell, it is still required to increase the efficiency of the energy conversion and to extend the operational lifetime. Accordingly, improvements for these properties are required.

EP 1271580A1 discloses a photo electrochemical cell. The application describes a metal oxide semiconductor layer (preferably TiO₂) where two particle sizes are mixed resulting in improved photon conversion efficiency. The smaller metal oxide particles are between 10 nm and 30 nm in size, while the larger particles are between 100 nm and 200 nm in size with the average particle size being between 30-50 nm. The porosity of the metal oxide layer is said to be between 45-55%. Preferably a two layer structure is used. Both electrodes use a glass substrate and the metal oxide layer is heat sintered, so that the individual particles connect to form a continuous porous structure.

US 2004/0226602 is titled “Porous film for use in an electronic device”. This application describes a porous film for use in a solar cell comprising at least two layers, each layer having a first kind of particles of average diameter of 2-25 nm and one layer having additionally a second kind of particles having an average diameter of 50 nm-1 μm. The two types of particles are different. This formulation provides an improvement in efficiency.

WO 2005/104153 discloses a method of producing a porous semiconductor layer by preparing an adhesion layer capable of providing electrical contact between the substrate and a porous semiconductor layer attached to the adhesion layer. A porous semiconductor layer is then prepared on a second substrate and is then transferred onto the adhesion layer. These steps may then be repeated to build up multiple layers. The semiconductor layer may comprise spherical nanoparticles as well as elongated rod-like nanoparticles or there may be spherical nanoparticles in one layer and elongated rod-like nanoparticles in the adjacent layer.

US 2005/0166960 discloses a photo electrochemical cell. This application covers a particulate structure containing a carbon nanotube lodged within a pore of a metal oxide semiconductor particle and attached to a metal oxide semiconductor layer. This structure results in improved electron transferring properties of the cell.

### SUMMARY OF THE INVENTION

The present invention therefore aims to provide a photovoltaic device having a more efficient energy conversion.

The present invention further aims to provide a photovoltaic device having a reduced decay time and therefore an extended operational lifetime.

The invention provides a photovoltaic device comprising an anode having a film of semiconductive particles deposited and sintered on a substrate, an electrolyte and a cathode, the anode comprising a single porous layer formed of a combination of two particle sizes of a metal oxide, the ratio of the percentage of larger particles to the percentage of smaller particles lying in the range 1:3 to 1:4.

### ADVANTAGEOUS EFFECT OF THE INVENTION

The use of a combination of metal oxide particle sizes in the porous semiconductor layer improves the initial performance of the photovoltaic devices. In addition, the rate at which the cell performance decays can be significantly reduced.

In addition, the use of a single layer structure is beneficial in terms of manufacturability leading to lower costs.

### BRIEF DESCRIPTION OF THE DRAWINGS

The invention will now be described with reference to the accompanying drawings in which:

FIG. 1 is a graph comparing initial performance of a device according to the invention and a control device; and

FIG. 2 is a graph comparing performance decay rate of a device according to the invention and a control device.

### DETAILED DESCRIPTION OF THE INVENTION

Each aspect of the present invention will now be discussed.

A working electrode includes, for example, a substrate and a conductive layer, upon which a layer of dye sensitised porous film of oxide semiconductor fine particles is deposited.

Examples of the substrate include, but are not limited to, a plastic, a glass, a metal, a ceramic, or the like.

Plastics that may be used as the substrate include, for example, polyethylene terephthalate (PET), polyethylene naphthalate (PEN), polybutylene terephthalate (PBT), a polyimide, and the like. Glasses that may be used as the substrate include, for example, borosilicate glass, quartz glass, soda glass, and the like. Metals that may be used as the substrate include, for example, titanium, nickel, and the like. Preferably, the substrate will be a plastic.

A conductive layer is deposited on the substrate, which will be made of a conductive metal oxide, such as indium doped tin oxide (ITO) if a plastic substrate is to be used. In the case of a glass, metal or ceramic substrate, a layer of fluorine doped tin oxide may be used. It is preferable that the conductive layer is substantially transparent.

The material constituting the substrate and the conductive layer must be resistant to the electrolyte. In the case in which an electrolyte containing iodine is used, copper and silver are unsuitable materials, for example, as they are readily attacked by the iodine and easily dissolve into the electrolyte.

The method used to form the conductive layer on the chosen support is not particularly limited and examples include any known film formation methods, such as sputtering methods, or CVD methods, or spray decomposition methods.

The oxide semiconductive porous film is a porous thin layer containing a combination of two or more particle sizes of a metal oxide, where the ratio of the percentage of larger particles to the percentage of smaller particles is in the range of 1:3 to 1:4 and the average particle size is in the range 50-75 nm. Metal oxide particles that may be used include titanium oxide (TiO₂), tin oxide (SnO₂), tungsten oxide (WO₃), zinc oxide (ZnO), niobium oxide (Nb₂O₅) and antimony oxide (Sb₂O₅). Preferably, the metal oxide particles will be titanium oxide (TiO₂).

The method for forming the oxide semiconductive porous film is not particularly limited. It can be formed, for example, by employing methods in which a dispersion solution that is obtained by dispersing commercially available oxide semiconductor fine particles in a desired dispersion medium, or a colloid solution that can be prepared using a sol-gel method is applied, after desired additives have been added if required, using a known coating method such as a screen printing method, an inkjet method, a roll coating method, a doctor blade method, a spin coating method, a spray coating method, or the like. Sintering of the oxide semiconductive porous film may be achieved via pressure or heat, depending on the substrate chosen.

The dye that is provided in the oxide semiconductive porous film is not particularly limited, and it is possible to use ruthenium complexes or iron complexes containing bipyridine structures, terpyridine structures, and the like in a ligand; metal complexes such as porphyrin and phthalocyanine; as well as organic dyes such as, but not limited to, eosin, rhodamine, coumarin, and melocyanine, or derivatives of the above. The dye can be selected according to the application and the semiconductor that is used for the oxide semiconductive porous film. Preferably, the dye will be a ruthenium complex.

For the electrolyte solution, it is possible to use, for example, a ‘polymer gel electrolyte’, an organic solvent electrolyte or an ionic liquid based electrolyte (room temperature molten salt) that in each case contain a redox pair.

The electrolyte is composed of a redox pair contained in a liquid solvent or a pseudo solid form (that permits ionic conduction or charge transport). The solvent for the liquid electrolyte can be a purely organic solvent or a so called ionic liquid (room temperature molten) of low volatility, or a combination of these components, and in turn the redox pair can contain a component that is considered a molten salt. The pseudo solid electrolyte can be considered by means of adding gelling agents to a liquid form of the electrolyte, for example by the use of polymers such as epichlorohydrin-co-ethylene oxide or poly(vinylidene fluoride-co-hexafluoropropylene) (PVDF-HFP), or sugars such as sorbitol derivatives or the addition of nanoparticles such as silica or other solids, e.g. Lithium salts. Alternatively it can be created through the addition of the redox pair to a system that is essential solid in certain areas of its phase diagram such as plastic crystals like succinonitrile. The polymer gelled electrolyte may in addition contain plasticisers such as for example propylene and/or ethylene carbonate.

Examples of the organic solvent include acetonitrile, methoxy acetonitrile, propionitrile, propylene carbonate and diethyl carbonate.

Examples of the ionic liquid include salts made of cations, such as quaternary imidazolium based cations and anions, iodide ions or bistrifluoromethyl sulfonylimido anions, dicyanoamide anions, and the like.

The redox pair that is contained in the electrolyte is not particularly limited. For example, combinations such as iodine with iodide ions or bromine with bromide ions may be used to create the redox pair.

Additives such as tert-butylpyridine and the like may also be added to the electrolyte.

The method for forming the electrolyte layer between the working electrode and the counter electrode includes for example, a method in which the electrodes are disposed facing each other and the electrolyte is supplied between the electrodes to form the electrolyte layer. Alternatively, the electrolyte may be dropped, applied or cast onto the working electrode or counter electrode to form the electrolyte layer and the other electrode may then be stacked on top. In order to prevent leakage of the electrolyte from the space between the working electrode and the counter electrode, it is preferable to seal the gap between the electrodes with an appropriate material.

The counter electrode includes an electron conductive material. The counter electrode may also be a conductive transparent substrate. The counter electrode may also be an electron conductive material coated on an electron insulating support. Specific examples of the electron conductive material include platinum, ITO and carbon, or combinations thereof. The counter electrode acts as a catalyst for the regeneration of the redox pair in the cell.

### EXAMPLES

In these examples the device is referred to as a solar cell. This wording should not be seen as limiting the invention.

### Example 1

### Initial Performance Improvement

Two titanium dioxide samples were dried in an oven at 90° C. overnight prior to use. These were a titanium dioxide sample which had an average particle size of 21 nm (Degussa Aeroxide P25, specific surface area (BET)=50+/−15 m²/g) and a titanium dioxide sample which had an average particle size of 170 nm (Kemira AFDC, specific surface area (BET)=10 m²/g).

The flexible DSSCs relating to the invention (cell A) and the comparison (cell B) were fabricated as follows. Approximately 13 μm thick nanoporous TiO₂ films were deposited onto 50 Ω/square ITO-PET by dispersing the dried TiO₂ in a mixture of dry Methyl Ethyl Ketone and Ethyl Acetate in the following ratios:

| | | | |
|---|---|---|---|
| Cell A: | Degussa P25 TiO₂ (21 nm particles) | 1.013 | g |
| | Kemira AFDC TiO₂ (170 nm particles) | 0.337 | g |
| | Methyl Ethyl Ketone | 45 | g |
| | Ethyl Acetate | 5 | g |
| Cell B: | Degussa P25 TiO₂ (21 nm particles) | 1.35 | g |
| | Methyl Ethyl Ketone | 45 | g |
| | Ethyl Acetate | 5 | g |

The resulting mixtures were sonicated for 15 minutes before being sprayed onto the conducting plastic substrate from a distance of approx 25 cm using a SATAminijet 3 HVLP spray gun with a 1 mm nozzle and 2 bar nitrogen carrier gas. The layers were allowed to dry in an oven at 90° C. for one hour, before being placed between two sheets of Teflon, sandwiched between two polished stainless steel bolsters and compressed with a force of 15 tonnes over the active area of the semiconductive porous layer for 15 seconds. The sintered layers were then allowed to dry for a further hour at 90° C.

The sintered layers were then sensitised by placing them in a 3×10⁻⁴ mol dm⁻³ ethanolic solution of ruthenium cis-bis-isothiocyanato bis(2,2′ bipyridyl-4,4′ dicarboxylic acid) overnight.

Platinum coated ITO-PET counter electrodes were prepared by sputter deposition under vacuum.

The dye sensitised TiO₂ layers and the platinum counter electrode were arranged in a sandwich type configuration with an I₂/I⁻ doped polymer electrolyte in between. The electrolyte comprised:

### 3 g Epichlorohydrin-co-ethylene-oxide

### 0.3 g Sodium Iodide

### 1.5 g Propylene Carbonate

### 1.5 g Ethylene Carbonate

### 0.03 g Iodine

dissolved in 250 ml Acetone

Penetration of the electrolyte into the pore structure of the dye sensitised TiO₂ layers was achieved by placing the coated layers onto a hot plate at approx 60° C. and applying 400 μl of the electrolyte, before applying the platinum coated ITO-PET counter electrode.

Following fabrication, the DSSCs were characterised by placing under a source that artificially replicated the solar spectrum in the visible region and was used to provide an irradiance of 10 mW/cm².

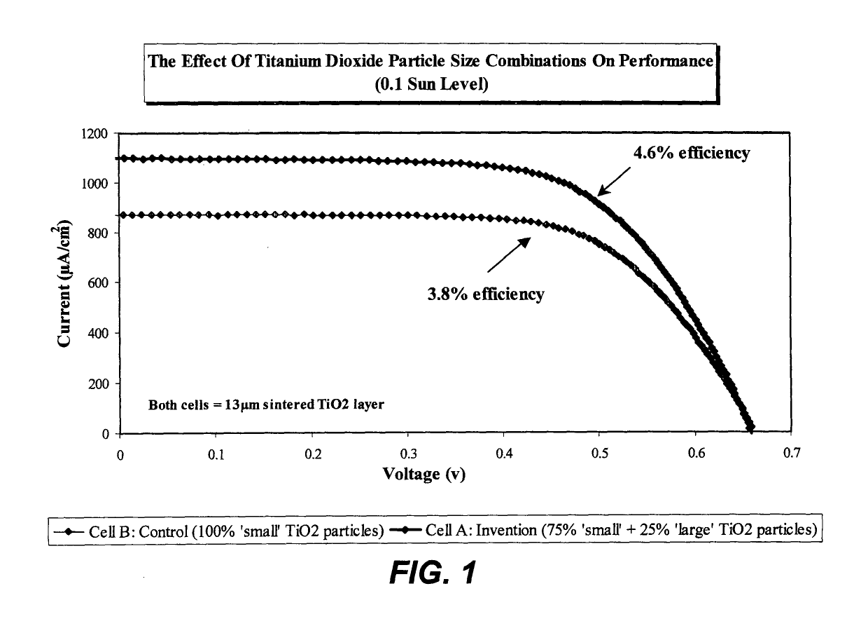

The data in FIG. 1 demonstrates that cell A (the invention comprising a combination of small and large TiO₂ particles) has superior performance compared to the control (cell B comprising 100% small particles) as shown by the higher current achieved.

### Example 2

### Reduced Rate of Decay

To assess the rate of decay of the DSSCs fabricated in example 1, the cells were tested under the source that artificially replicated the solar spectrum in the visible region to provide an illumination of 0.10 sun over a period of time and the percentage loss of initial efficiency was recorded.

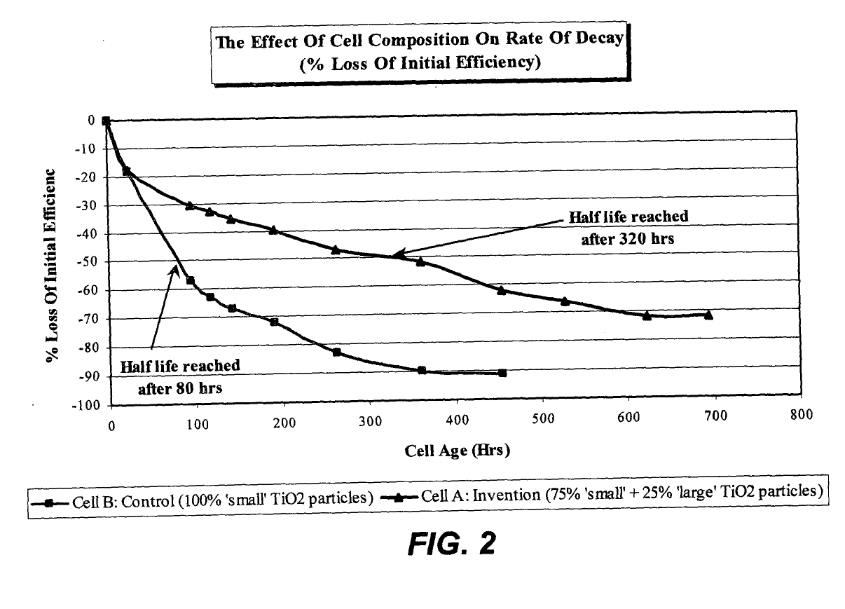

The data in FIG. 2 demonstrates that cell A (the invention comprising a combination of small and large TiO₂ particles) has a significantly slower rate of decay compared to the control (cell B comprising 100% small particles). It can be seen that the control (cell B) reaches it's half-life (i.e. the efficiency had dropped to 50% of its initial performance) after only 80 hours, compared to a half life of 320 hours for cell A (the invention).

These examples demonstrate that through the use of a combination of titanium dioxide particles of varying size, which once sintered form the mesoporous anode, the initial performance of the solar cell can be improved. In addition, the rate at which the cell decays can be significantly reduced.

The examples above refer to titanium dioxide. It will be understood by those skilled in the art that any suitable metal oxide can be used and will provide the same advantages. Similarly although the examples refer to a gelled electrolyte the invention is not so limited. A liquid electrolyte could be used.

The invention has been described in detail with reference to preferred embodiments thereof. It will be understood by those skilled in the art that variations and modifications can be effected within the scope of the invention.

1. A photo voltaic device comprising an anode having a film of semiconductive particles deposited and sintered on a substrate, an electrolyte and a cathode, the anode comprising a single porous layer formed of a combination of two particle sizes of a metal oxide, the ratio of the percentage of larger particles to the percentage of smaller particles lying in the range 1:3 to 1:4 and the average porosity of the porous layer lying between 70-75%.

2. A device as claimed in claim 1 wherein the average particle size is in the range 50-75 nm.

3. A device as claimed in claim 2 wherein the larger particles are approximately 170 nm and the smaller particles are approximately 20 nm.

4. (canceled)

5. A device as claimed in claim 1 wherein the substrate is flexible.

6. A device as claimed in claim 1 wherein the electrolyte is a gelled electrolyte.

7. A device as claimed in claim 1 wherein the metal oxide is titanium dioxide.
